(19) United States
(12) Patent Application Publication
(10) Pub. No.: US 2008/0007899 A1
(43) Pub. Date: Jan. 10, 2008

(54) Casing assembly of computer power supply

(76) Inventor: Kun-Hsiang Shieh, Taipei Hsien (TW)

Correspondence Address: Kun-Hsiang Shieh, 235 Chung-Ho, Box 8-24, Taipei, omitted

(21) Appl. No.: 11/481,276

(22) Filed: Jul. 6, 2006

(30) Foreign Application Priority Data
Jul. 4, 2006 (TW) 094211216

(51) Int. Cl. H05K 5/00

(52) U.S. Cl. 361/679; 312/223.1

(57) ABSTRACT

A casing assembly of a computer power supply comprises a casing and a cover; a predetermined position of a bottom plate of the casing having a recess portion; one side of the power supply being installed in the recess portion and the cover is coverable upon the casing. The recess portion and the bottom plate are integrally formed. A predetermined position of the bottom plate of the casing has a hole; and an edge of a carrier seat is extended with a folded surface. A bottom of the carrier seat is formed as a stepped concave surface. The carrier seat and the folded surface is positioned upon the hole so that the bottom plate of the casing is formed with an recess portion. A bottom surface of the bottom plate is installed with a leg; and a depth of the recess portion is equal to a height of the leg.

### FIELD OF THE INVENTION

The present invention relates to computer power supplies, in particular to a casing assembly of a computer power supply, wherein a the power supply can be installed upon the recess portion of a casing so as to save the occupied space in the bottom plate and the back plate.

### BACKGROUND OF THE INVENTION

Referring to FIGS. 1 and 2, the prior art computer casing 10, 20 has an accessing unit 11, 21. The back plate 12, 22 is corresponding to the form (such as ATX, Baby, ATX) of a mainframe (not shown) and has a plurality of slots 13, 23. Other space is formed with a via hole 14, 24 for installing a fan and a power supply 15, 25.

Since the installation of the power supply 15, 25 must consider the arrangement of the back plate 12, 22, the slots 13, 23 and the fan via hole 14, 24. When a large scale mainframe (such as ATX), is installed in the casing 10, the back plate 12 must have seven slots 13 and thus the space of the back plate 32 is insufficient. Thus only a micro power supply 15 can be used, which is a low power device and is not a main trend in the market and thus is expensive. If the back plate 32 is installed with a widely used and cheap PS/2 power supply 25, since it is large and thus occupies a great space in the back plate 32, only three slots can be used and thus only small type mainframes (such as Baby ATX) are suitable. The number of slots is few and thus it is difficult to expand with other components. Furthermore, the mainframe generally has an all-in-one structure. It is not widely used and thus is expensive.

### SUMMARY OF THE INVENTION

Accordingly, the primary object of the present invention is to provide a casing assembly of a computer power supply, wherein a power supply can be installed upon the recess portion so as to save the occupied space in the bottom plate and the back plate. Thus mainframes of different forms can be installed therein. Thereby the present invention is convenient and economic. Thereby a height of the casing 3 can be reduced so that the casing is compact and light weighted.

To achieve above object, the present invention provides a casing assembly of a computer power supply which comprises a casing and a cover; a predetermined position of a bottom plate of the casing having a recess portion; one side of the power supply being installed in the recess portion and the cover is coverable upon the casing. The recess portion and the bottom plate are integrally formed.

A predetermined position of the bottom plate of the casing has a hole; an edge of a carrier seat is extended with a folded surface; a bottom of the carrier seat is formed as a stepped concave surface; the carrier seat and the folded surface is positioned upon the hole so that the bottom plate of the casing is formed with an recess portion. A bottom surface of the bottom plate 35 is installed with a leg; and a depth of the recess portion is equal to a height of the leg. A back plate of the casing has an opening corresponding to the power supply.

The various objects and advantages of the present invention will be more readily understood from the following detailed description when read in conjunction with the appended drawing.

### BRIEF DESCRIPTION OF THE DRAWINGS

FIG. 1 shows a prior art computer casing.

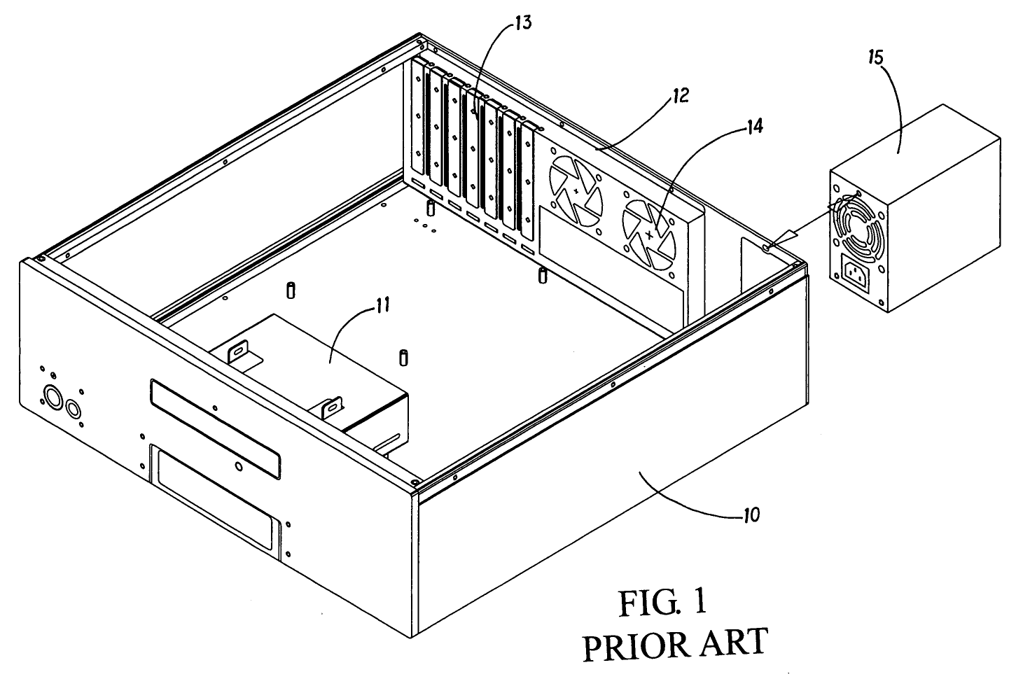

FIG. 2 shows another prior art computer casing.

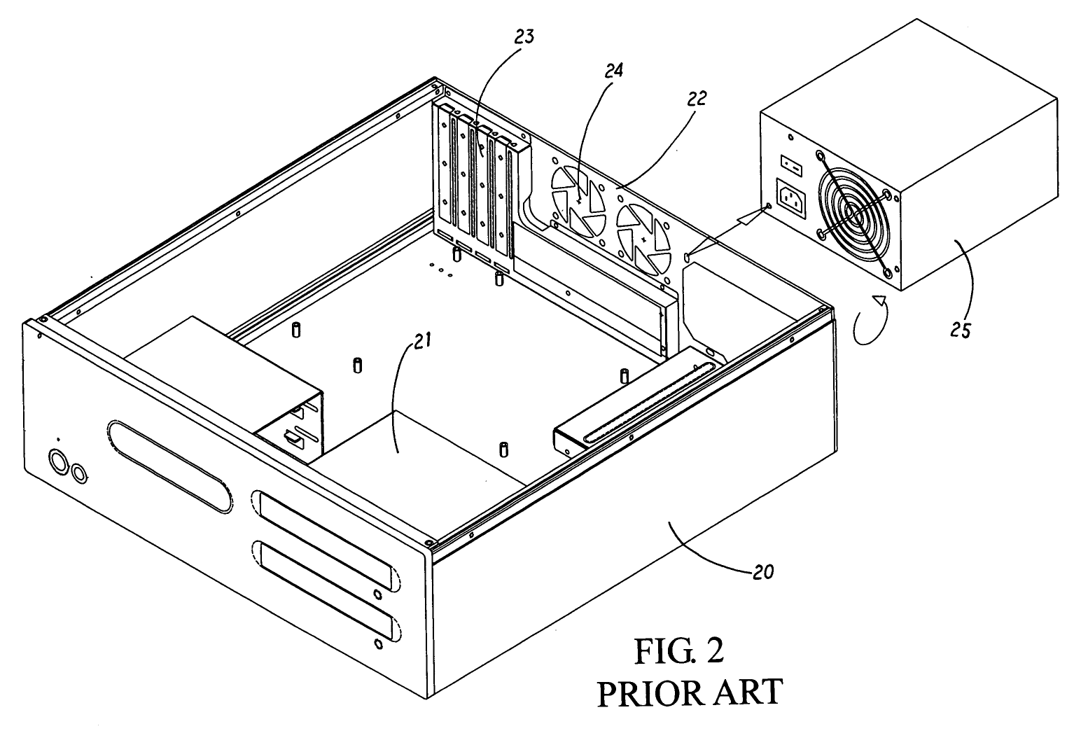

FIG. 3 is a structural schematic view of the present invention.

FIG. 4 is an assembled view of the present invention, where the cover is not illustrated.

FIG. 5 is a rear view of the bottom plate of the casing of the present invention.

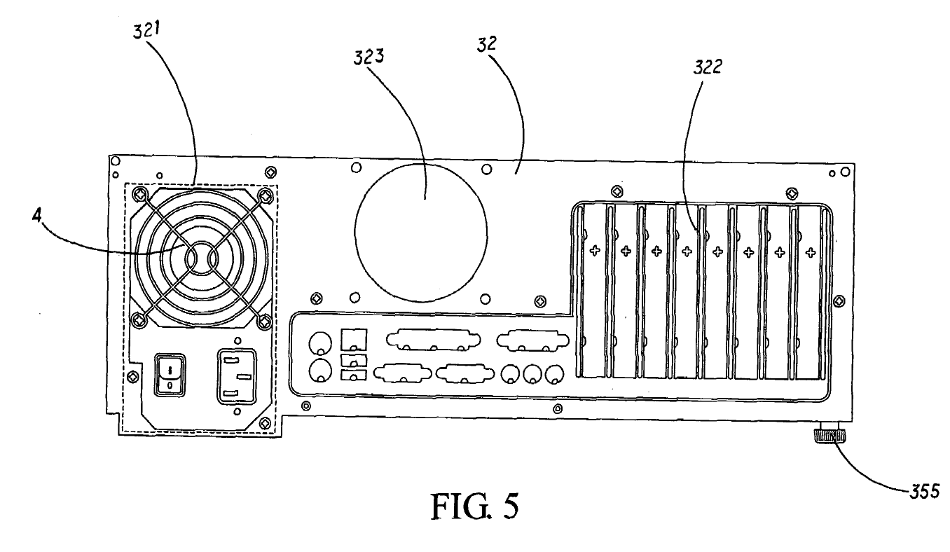

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

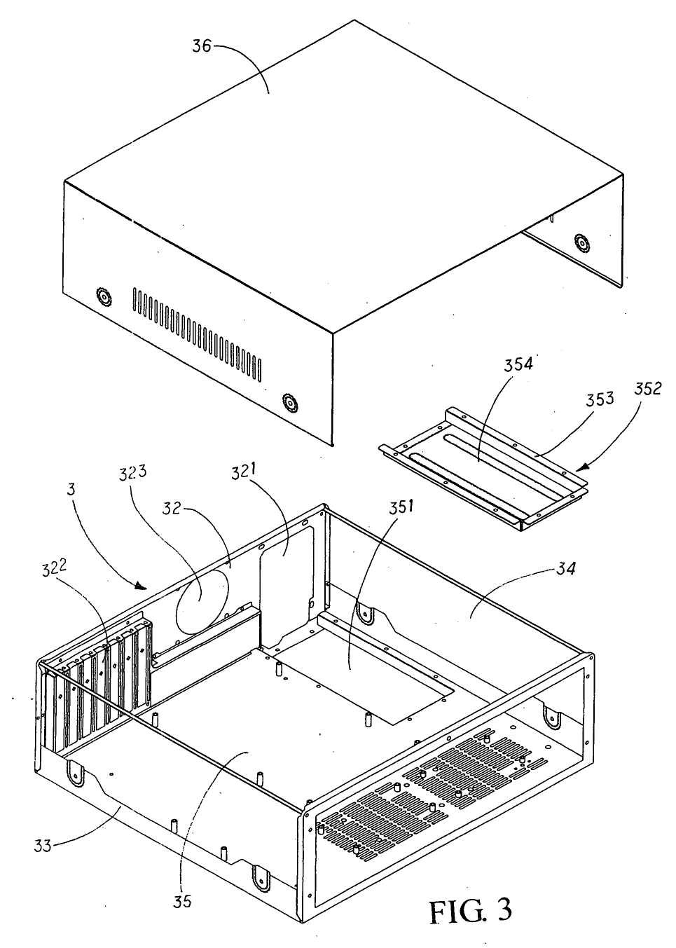

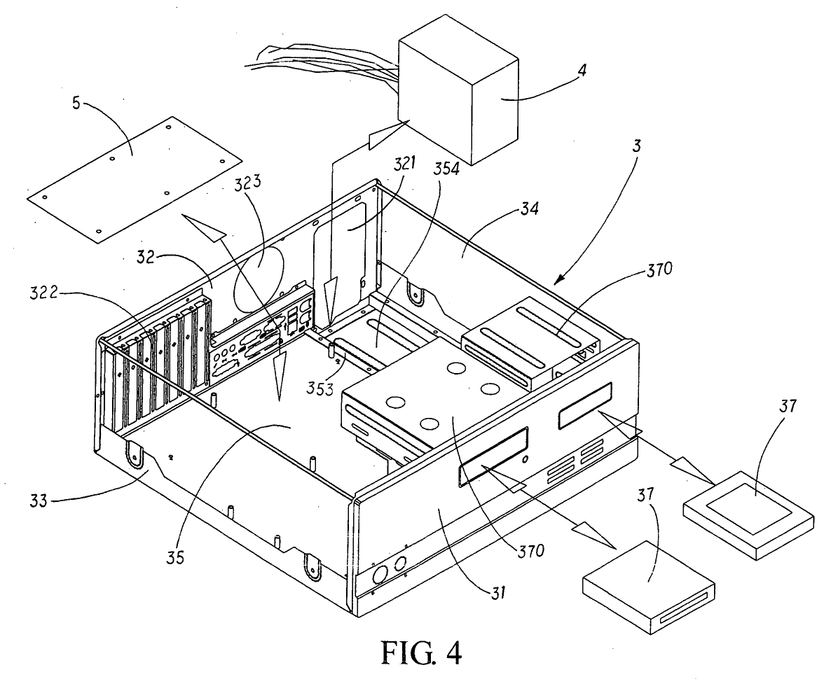

Referring to FIGS. 3 and 4, the structure of a computer power supply of the present invention is illustrated. A casing 3 includes a front plate 31, a back plate 32, two lateral plates 33, 34, a bottom plate 35, and a cover 36. An accessing unit 37 is installed in a frame body 370. The frame body 370 is positioned at an inner side of the front plate 31. A predetermined position of the bottom plate 35 of the casing 3 has a hole 351. An edge of a carrier seat 352 is extended with a folded surface 353. A bottom of the carrier seat 352 is formed as a stepped concave surface 354. The carrier seat 352 and the folded surface 353 is positioned upon the hole 351 so that the bottom plate 35 of the casing 3 is formed with an recess portion (referring to FIG. 4). A bottom surface of the bottom plate 35 is installed with a leg 355. Preferably, the depth of the recess portion is equal to the height of the leg 355. Preferably, the specification of the power supply is PS/2. A long straight edge of the power supply 4 is installed in the recess portion. The cover 36 is coverable upon the casing 3. The back plate 32 of the casing 3 is formed with an opening 321 corresponding to the power supply 4 for providing a space for receiving wires and heat dissipation of the computer and power supply. A mainframe 5 arranged upon the back plate 32 is formed with a plurality of slots 322 and a via hole 323. By above mentioned features, the power supply 4 can be installed upon the recess portion so as to save the occupied space in the bottom plate 35 and the back plate 32. Thus mainframes of different forms can be installed therein. Thereby the present invention is convenient and economic. A height of the casing 3 can be reduced so that the casing 3 is compact and light weighted.

Moreover, in the present invention, the bottom plate 35 has an integral formed structure and the recess portion with a stepped concave surface 354 is formed at a predetermined position thereof. However this can be formed by punching which is known in the prior art and thus the details will not be further described herein.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A casing assembly of a computer power supply comprising a casing and a cover; a predetermined position of a bottom plate of the casing having a recess portion; one side of the power supply being installed in the recess portion and the cover is coverable upon the casing.

2. The casing assembly of a computer power supply as claimed in claim 1, wherein the recess portion and the bottom plate are integrally formed.

3. The casing assembly of a computer power supply as claimed in claim 1, wherein a predetermined position of the bottom plate of the casing has a hole; an edge of a carrier seat is extended with a folded surface; a bottom of the carrier seat is formed as a stepped concave surface; the carrier seat and the folded surface is positioned upon the hole so that the bottom plate of the casing is formed with an recess portion.

4. The casing assembly of a computer power supply as claimed in claim 1, wherein a bottom surface of the bottom plate is installed with a leg; and a depth of the recess portion is equal to a height of the leg.

5. The casing assembly of a computer power supply as claimed in claim 1, wherein the power supply is a PS/2 power supply.

6. The casing assembly of a computer power supply as claimed in claim 1, wherein a back plate of the casing has an opening corresponding to the power supply.
